(19) United States
(12) Patent Application Publication
(10) Pub. No.: US 2006/0199308 A1
(43) Pub. Date: Sep. 7, 2006

(54) Process for manufacturing sawing type leadless semiconductor packages

(75) Inventors: Yong-Gill Lee, Kaohsiung (TW); Jin-Young Hong, Kaohsiung (TW); Hyung-Jun Park, Kaohsiung (TW); Jin-Hee Won, Kaohsiung (TW)

Correspondence Address: TROXELL LAW OFFICE PLLC, SUITE 1404, 5205 LEESBURG PIKE, FALLS CHURCH, VA, 22041, US

(73) Assignee: Advanced Semiconductor Engineering, Inc.

(21) Appl. No.: 11/068,799

(22) Filed: Mar. 2, 2005

(51) Int. Cl. H01L 21/50

(52) U.S. Cl. 438/110

(57) ABSTRACT

A process for manufacturing sawing type leadless semiconductor packages includes a post mold-curing step, which is performed after an encapsulant is formed and after connecting bars of a leadframe are removed. The connecting bars are formed between a plurality of package units of the leadframe to connect a plurality of leads in the package units. After die attachment and electrical connection, the encapsulant is formed over the package units and the connecting bars to encapsulate the chips. The connecting bars are removed prior to the post mold-curing step. Therefore the encapsulant can be cured without deformation or warpage, thereby facilitating the sequent processes.

### FIELD OF THE INVENTION

The present invention relates to a process for manufacturing a plurality of leadless semiconductor packages, and more particularly, to a process for manufacturing a plurality of sawing type leadless semiconductor packages to reduce package deformation and warpage.

### BACKGROUND OF THE INVENTION

Compared to the conventional semiconductor packages, which have outer leads extended from the sides of the molding compound, leadless semiconductor packages utilize the exposed lower surfaces of the inner leads from a leadframe for outer electrical connection. Leadless semiconductor packages have smaller footprints and shorter signal paths to match the requirements of low cost packages for high frequency and small dimension integrated circuits.

The leadless semiconductor packages can be further divided into sawing type and punch type according to the singulation methods. According to the sawing type packages, an encapsulant is formed over a plurality of package units and cutting streets of a leadframe by either molding or printing techniques. Then the encapsulant is diced to form a plurality of individual packages by a sawing tool. According to the punch type packages, individual encapsulants are formed on the leadframe by using the molding technique. Then a punch tool is used to separate the leadframe into individual package units after it has been molded. In most cases, the encapsulants are formed without covering the cutting streets by using a mold tool with a plurality of mold cavities being positioned corresponding to the package units of a leadframe. Accordingly, the cutting streets between the package units for punch type leadless semiconductor packages needs to be wider, therefore, the total number of the package units on a leadframe is fewer.

Although the leadframe for the sawing type semiconductor packages can include more package units than that of the punch type packages on the same dimension of a leadframe, unexpected deformation and warpage are encountered during the manufacturing of the sawing type leadless semiconductor packages. In FIG. 1, a conventional process flow for manufacturing sawing type leadless semiconductor packages is shown. Referring to FIGS. 1 and 2, in step 1, a leadframe 10 for sawing type packages has a plurality of leads 11 and a die pad 12 in each package unit, and a plurality of connecting bars 13 between the package units. Connecting bars 13 are formed through the cutting streets for connecting the leads 11. It is well known that a plating layer 20, made of materials such as Silver (Ag), is formed on the upper surface of the leadframe 10 to enhance wire-bonding reliabiiity. In step 2, a plurality of chips 30 are individually disposed on the die pads 12 and electrically connected to the leads 11 through a plurality of bonding wires 40. In step 3, an encapsulant 50 is formed over the cutting streets and the package units of the leadframe 10 to cover the connecting bars 13, the chips 30, and the bonding wires 40. Due to CTE mismatch between the encapsulant 50 and the leadframe 10, internal stress is generated in the connecting bars 13, which cause serious deformation and warpage of the molded encapsulant 50, leading to difficulties in performing the sequent packaging processes, such as plating on the external terminals, electrical testing or sawing. Currently, one of the known solutions is to design wider cutting streets between the package units. However, the total number of package units per leadframe will be fewer, moreover, the sawing times will increase.

U.S. Pat. No. 6,489,218 discloses a known method for manufacturing leadless semiconductor packages. After chip attachment, an encapsulant is formed over a leadframe and then cured. However, this method still cannot effectively solve the warpage problem, which makes the sawing process more difficult.

### SUMMARY OF THE INVENTION

The primary objective of the present invention is to provide a process for manufacturing a plurality of sawing type leadless semiconductor packages. A leadframe has a plurality of leads located in each package unit and a plurality of connecting bars between the package units. A post mold-curing (PMC) step is performed to cure the encapsulant after a plurality of connecting bars of the leadframe are removed. Thus, internal stress will not be generated in or transmitted through the connecting bars to reduce the deformation and warpage of the encapsulant to facilitate the sequent packaging steps, such as plating on the external terminals, electrical test, or sawing.

According to the present invention, a process for manufacturing a plurality of sawing type leadless semiconductor packages is disclosed. Initially, a leadframe including a plurality of package units arranged in a matrix is provided. The leadframe has a plurality of connecting bars to connect the leads in the package units. Then, a plurality of chips are disposed on either the die pads of the leadframe or a back tape. Furthermore, the chips are electrically connected to the leads through a plurality of bonding wires. Next, an encapsulant is formed over the package units and the connecting bars to encapsulate the chips, the leads and the connecting bars. By maintaining the encapsulant in the partially cured condition, the connecting bars are removed, and then a post mold-curing step is performed to fully cure the encapsulant. Finally, a sawing step is performed to dice the encapsulant to form a plurality of individual leadless semiconductor packages. Thereby, the impact of the deformation and warpage of the encapsulant can be reduced or even eliminated.

### DESCRIPTION OF THE DRAWINGS

FIG. 1 is a process flow of a known manufacturing process for sawing type leadless semiconductor packages.

FIG. 2 is a cross-sectional view of the leadless semiconductor packages before sawing in the known manufacturing processes.

FIG. 3 is a process flow for manufacturing a plurality of sawing type leadless semiconductor packages according to the preferred embodiment of the present invention.

FIG. 4A to FIG. 4J are cross-sectional views of the leadframe, illustrating the manufacturing processes according to the preferred embodiment of the present invention.

FIG. 5 is a top view of the leadframe according to the preferred embodiment of the present invention.

FIG. 6 is a top view of the partially enlarged upper surface of the leadframe at section 6 of FIG. 5 according to the preferred embodiment of the present invention.

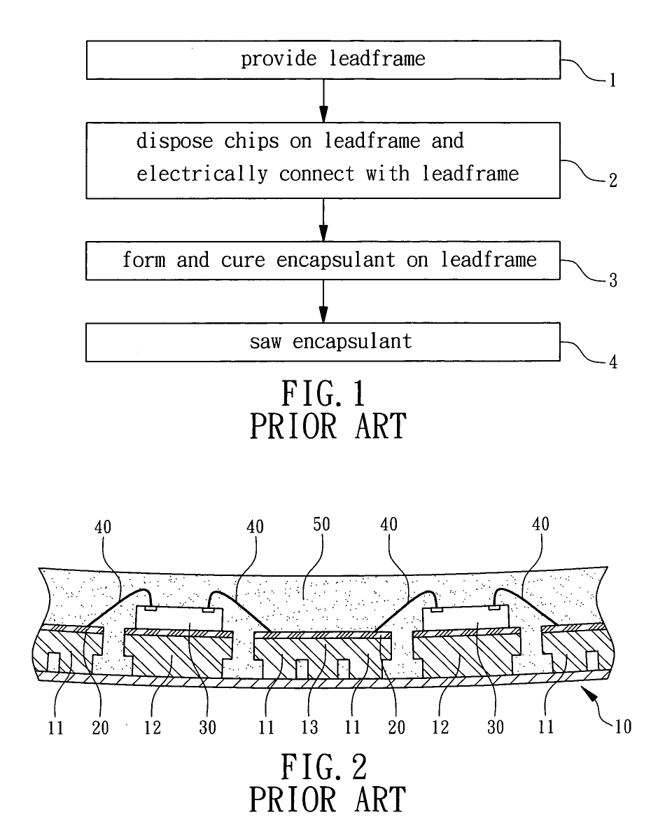

### DETAILED DESCRIPTION OF THE PRESENT INVENTION

Referring to the drawings attached, the present invention is described by means of the embodiment(s) below.

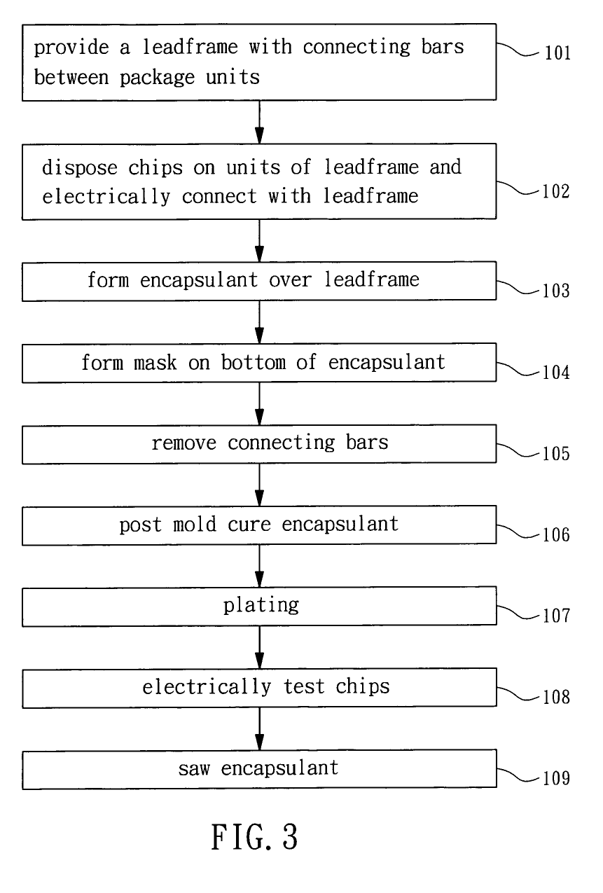

A process flow for manufacturing sawing type leadless semiconductor packages is illustrated in FIG. 3 according to the preferred embodiment of the present invention.

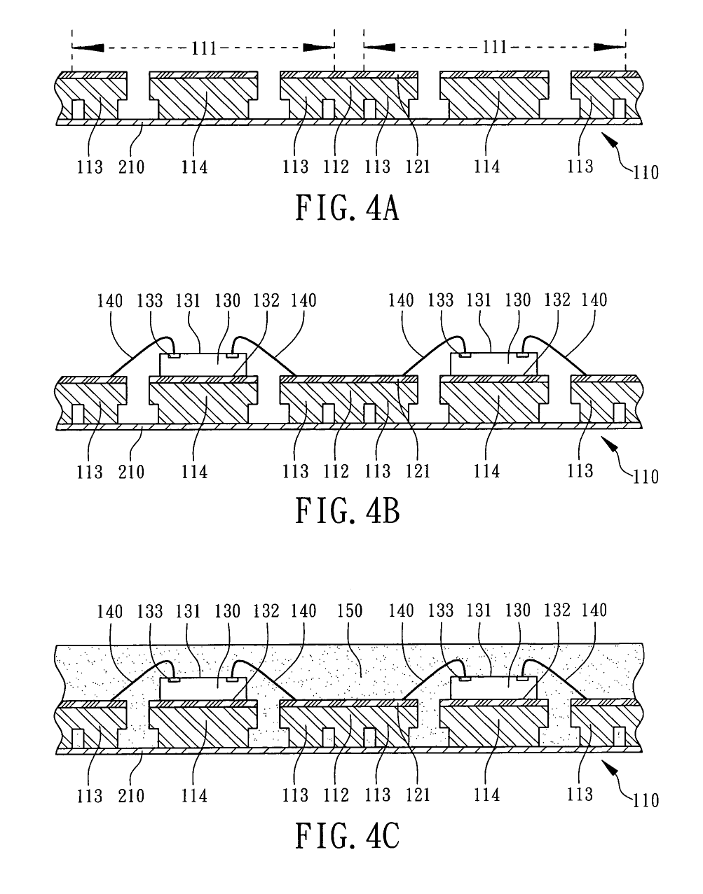

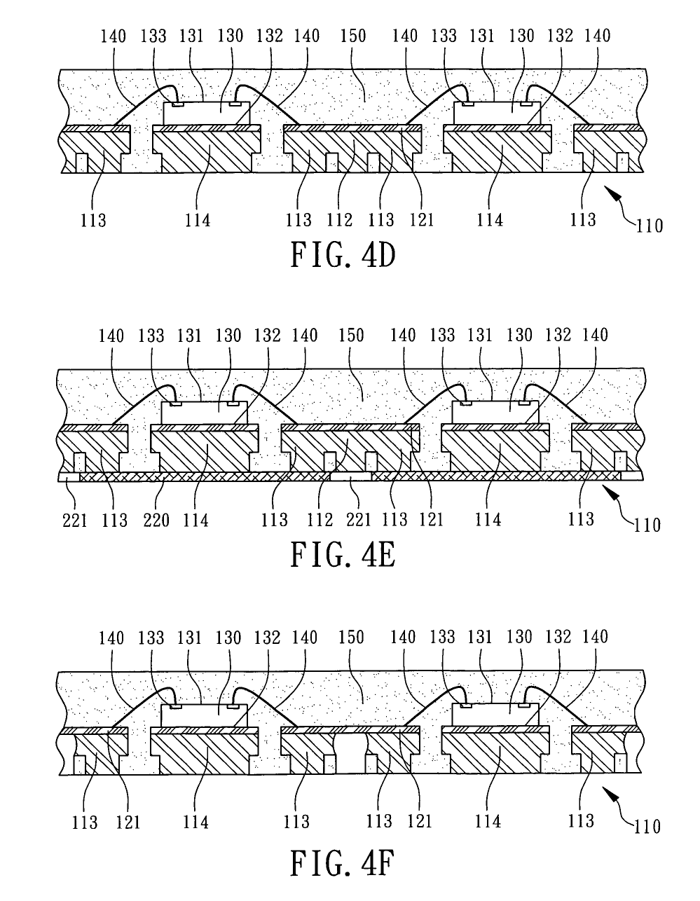

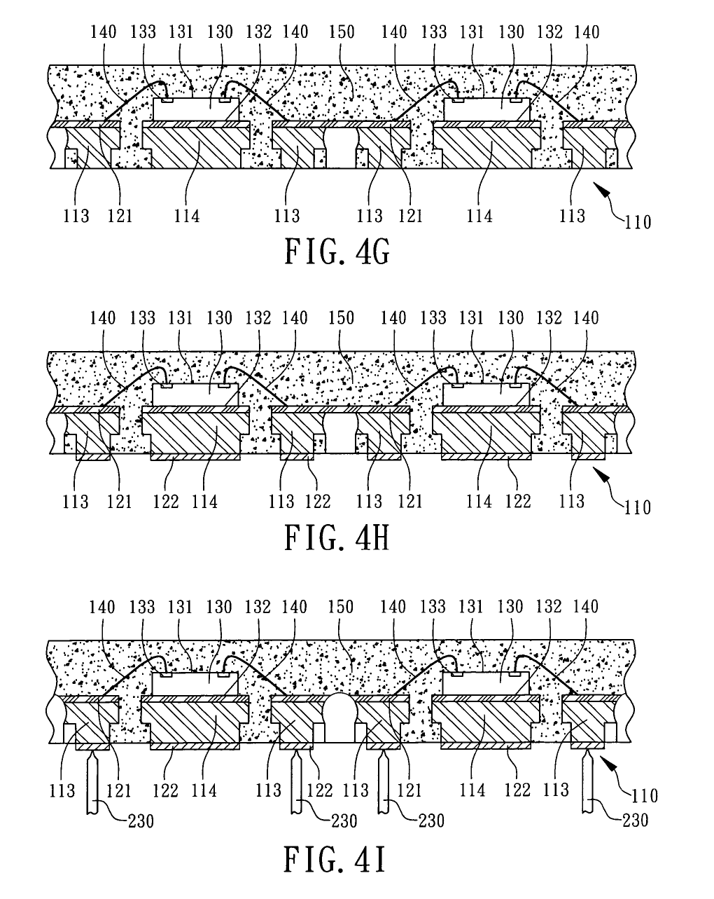

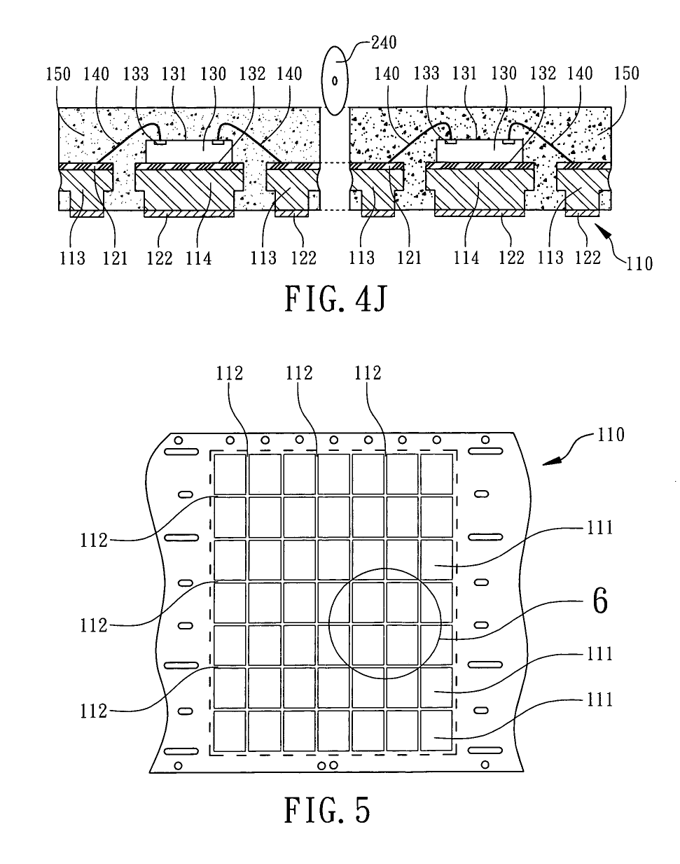

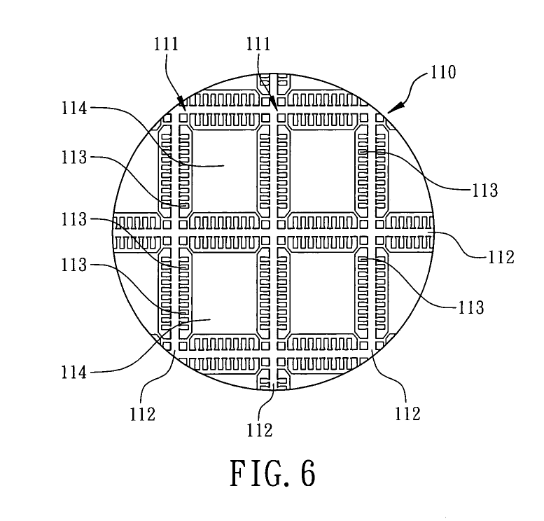

As shown in FIG. 4A and FIG. 5, in step 101, a leadframe 110 including a plurality of package units 111 is provided. The package units 111 are arranged in a matrix as shown in FIG. 5. A plurality of connecting bars 112 are formed between the package units 111. Referring to FIG. 6, the leadframe 110 has a plurality of leads 113 in each package unit 111. The leads 113 are integrally connected to the leadframe 110 through the connecting bars 112. Preferably, the leadframe 110 further has a plurality of die pads 114 for supporting the chip 130. Preferably, the leads 113 are arranged around the die pad 114 suitable for manufacturing QFN packages (Quad Flat Non-leaded package). Leadframe 110 is made of metal, such as copper, iron or alloys containing copper or iron. Referring to FIG. 4A again, a first plating layer 121 like Ag or Ni—Au can be formed in advance on the upper surface of the leadframe 110 for wire-bonding connection. Moreover, in this embodiment, a plurality of indentations are formed in the lower surface of the leadframe 110 between the leads 113 and the connecting bars 112. In step 101, it is preferable to attach a back tape 210 to the lower surface of the leadframe 110 (including the lower surfaces of leads 113, the lower surfaces of die pad 114 and the lower surfaces of connecting bar 112) in order to enhance the stability of the leadframe 110 during packaging processes and to prevent mold flash deposited on the lower surface of leadframe 110.

Next, in step 102, a plurality of chips 130 are disposed on the package unit 111 of the leadframe 110 as shown in FIG. 4B. Each chip 130 has an active surface 131 and a back surface 132 with a plurality of bonding pads 133 formed on the active surface 131. The back surfaces 132 are attached to the upper surfaces of the die pad 114 or to the back tape 210. Furthermore, the chips 130 are electrically connected to the leadframe 110 by using the method of wire bonding. In this embodiment, a plurality of bonding wires 140 are utilized to connect the bonding pads 133 of the chips 130 with the leads 113 of the leadframe 110 so as to electrically connect the chips 130 with the leadframe 110. The first plating layer 121 can improve the bonding strength of the bonding wires 140 on the leads 113. In another embodiment, the chip 130 may be bumped chips, which are flip-chip mounted on the leads 113 (not shown in the drawings).

As shown in FIG. 4C, in step 103, an encapsulant 150 is formed over the package units 111 and the connecting bars 112, corresponding to the matrix by either molding or printing methods. The encapsulant 150 encapsulates the chips 130, the upper surfaces of the leads 113 and the upper surfaces of the connecting bars 112. In step 103, the encapsulant 150 is maintained in a partially cured condition, such as B-stage. Preferably, the indentations formed between the leads 113 and the connecting bars 112 are filled with the encapsulant 150 so that the leads 113 can be firmly fixed during the processes. Moreover, the leads 113 will not be over-etched when the connecting bars 112 are removed (in step 105). Furthermore, the encapsulant 150 is higher than the active surface 131 of the chip 130 and the loop height of bonding wires 140 to adequately seal the chip 130 and the bonding wires 140. Additionally, the bottom of the encapsulant 150 is covered by the back tape 210 or mold cavities of a mold tool. Referring to FIG. 4D, when the back tape 210 is removed from the encapsulant 150, the lower surfaces of the leads 113 and the lower surfaces of the connecting bars 112 and the lower surfaces of the die pad 114 are exposed from the encapsulant 150. As shown in FIG. 4E, in step 104, a mask 220 is formed on the bottom of the encapsulant 150 and on the lower surface of leadframe 110 which covers the exposed lower surfaces of the leads 113 and the exposed lower surfaces of the die pads 114. This is done prior to removing the connecting bars 112 (step 105). Mask 220 is an ultra violet (UV) tape and is attached to the encapsulant 150 according to this embodiment. Mask 220 is done by exposing and developing techniques to expose the lower surfaces of the connecting bars 112. In step 105, the connecting bars 112 are removed prior to the post mold-curing step 106. Leadframe 110 in step 105 is shown in FIG. 4F, the connecting bars 112 are removed by wet etching or dry etching processes to separate the leads 113 without introducing or transmitting unwanted stress. Mask 220 can be removed by detaping or by using stripping solutions.

Then the post mold-curing step 106 is performed. Referring to FIG. 4C, the assembly of the encapsulant 150 and the leadframe 110 without the connecting bars 112 is placed inside a furnace to fully cure the encapsulant 150 where the encapsulant 150 is transformed into C-stage. Due to the disappearance of the connecting bars 112, the encapsulant 150 will not have serious warpage during the post mold-curing step 106, to facilitate the steps of 107, 108 and 109, mentioned below.

Next, the plating step 107 is performed, if desired. Referring to FIG. 4H, a second plating layer 122 is electroplated on the lower surfaces of the leads 113 through the electrical connection of the first plating layer 121 for outer electrical connection and anti-oxidation. In this embodiment, the second plating layer 122 may further be formed on the lower surfaces of the die pads 114.

It is better to perform step 108 that the encapsulated chips 130 are electrically tested before or after the sawing step 109. Referring to FIG. 41, the exposed portions of the first plating layer 121 are cut off to electrically isolate the leads 113, and then a probe card 230 is used for probing the lower surfaces of the leads 113 for electrical test of the encapsulated chips 130. Since there is no serious warpage on the encapsulant 150, probe card 230 can precisely probe on the lower surfaces of the leads 113.

Finally, the sawing step 109 is performed. As shown in FIG. 4J, a sawing tool 240 is utilized for sawing the encapsulant 150 to form a plurality of individual leadless semiconductor packages. Without serious warpage on the encapsulant 150, the sawing tool 240 may precisely saw the encapsulant 150 without electrical short.

While the present invention has been specifically illustrated and described in detail with respect to the preferred embodiments, it will be clearly understood by those skilled in the field, various changes in form and detail may be made without departing from the spirit and scope of this present invention.

What is claimed is:

1. A process for manufacturing a plurality of semiconductor packages, comprising:
providing a leadframe including a plurality of package units arranged in a matrix and having a plurality of leads located in each package unit and a plurality of connecting bars between the package units, wherein the connecting bars connect the leads;
disposing a plurality of chips on the package units;
electrically connecting the chips with the leads of the leadframe;
forming an encapsulant over the package units and the connecting bars to encapsulate the chips, the leads and the connecting bars;
removing the connecting bars;
performing a post mold-curing step to cure the encapsulant after the connecting bars are removed; and
performing a sawing step to dice the encapsulant to form a plurality of individual semiconductor packages.

2. The process in accordance with claim 1, wherein lower surfaces of the connecting bars and lower surfaces of the leads are exposed from the encapsulant.

3. The process in accordance with claim 2, wherein the connecting bars are removed by etching.

4. The process in accordance with claim 3, further comprising the step of forming a mask on a bottom of the encapsulant to cover the lower surfaces of the leads.

5. The process in accordance with claim 4, wherein the mask is a UV tape and is attached to the encapsulant.

6. The process in accordance with claim 1, wherein the leadframe further has at least a die pad in each package unit.

7. The process in accordance with claim 1, wherein a first plating layer is formed on upper surfaces of the leads.

8. The process in accordance with claim 7, wherein the first plating layer includes silver (Ag).

9. The process in accordance with claim 7, further comprising the step of electroplating a second plating layer on lower surfaces of the leads through electrical connection of the first plating layer after the connecting bars are removed.

10. The process in accordance with claim 1, further comprising the step of electrically testing the chips through probing the leads after the post mold-curing step.

11. The process in accordance with claim 10, wherein the step of electrically testing the chips is performed prior to the sawing step.

12. The process in accordance with claim 1, wherein a back tape is attached to the leadframe before forming the encapsulant, and the back tape is removed after the encapsulant is formed.

13. The process in accordance with claim 1, wherein the chips are electrically connected to the leads through a plurality of bonding wires.

14. The process in accordance with claim 1, wherein the semiconductor packages are QFN (Quad Flat Non-leaded) packages.

15. The process in accordance with claim 1, wherein the encapsulants are formed by molding.
